(19) United States
(12) Patent Application Publication
(10) Pub. No.: US 2025/0355023 A1
(43) Pub. Date: Nov. 20, 2025

(54) ARTIFICIAL INTELLIGENCE WAVEFORM ASSISTANT

(71) Applicant: Tektronix, Inc., Beaverton, OR (US)

(72) Inventors: Christopher N. White, Cedar Park, TX (US); Sam J. Strickling, Cypress, TX (US); Keith D. Rule, Beaverton, OR (US); Abdul Bailey, Queen Creek, AZ (US)

(21) Appl. No.: 19/204,320

(22) Filed: May 9, 2025

Related U.S. Application Data
(60) Provisional application No. 63/649,204, filed on May 17, 2024.

(51) Int. Cl. G01R 13/02

(52) U.S. Cl. CPC G01R 13/0218

(57) ABSTRACT

A computing device includes one or more memories including test and measurement knowledge, a generative artificial intelligence (AI) model having access to the one or more memories, a display, user controls to allow the user to provide inputs, and one or more processors configured to execute that code that causes the one or more processors to: access an application programming interface (API) of an AI assistant for the generative AI model to allow the user to interact with the AI assistant, receive one or more user inputs through one or more of the API or a user interface, the user inputs providing a description of one or more waveforms to be generated, use the AI assistant to develop each waveform definition from the description and access the generative AI model, receive one or more waveforms from the AI assistant, and store the one or more waveforms.

### CROSS-REFERENCE TO RELATED APPLICATIONS

This disclosure is a non-provisional of and claims benefit from U.S. Provisional Application No. 63/649,204, titled “ARTIFICIAL INTELLIGENCE WAVEFORM ASSISTANT,” filed on May 17, 2024, the disclosures of which is incorporated herein by reference in their entirety.

### TECHNICAL FIELD

This disclosure relates to test and measurement instruments, and more particularly to artificial intelligence agents for test and measurement instruments.

### BACKGROUND

The use of machine learning for testing and measuring performance of electronic devices drastically speeds up and improves design testing and verification and manufacturing line production. An issue may arise in some machine learning environments because of the lack of large data sets related to standards, different signal impairment used for testing, and different instruments. The issue of lack of datasets is especially true for emerging standards for which hardware is unavailable or in short supply.

### BRIEF DESCRIPTION OF THE DRAWINGS

FIG. 1 shows an embodiment of a system to generate waveforms for a test system.

FIG. 2 shows a flowchart of an embodiment of method of generating waveforms for a test system.

FIG. 3 shows a flowchart of an alternative embodiment of a method of generating waveforms for a test system.

### DESCRIPTION

The embodiments herein involve using generative artificial intelligence (AI) models, such as large language models (LLMs), in association with knowledge and functions related to standards, impairments, and instruments to create waveform files. In some examples, the present disclosure demonstrates the use of generative AI models to create tensors.

Some machine learning systems and processes use tensors as input a machine learning system. The tensor comprises a waveform image or images generated by a device under test (DUT). The tensor may include bar graphs and other data. Examples of tensors are disclosed in U.S. patent application Ser. No. 17/747,954, “SHORT PATTERN WAVEFORM DATABASE BASED MACHINE LEARNING FOR MEASUREMENT,” filed Apr. 18, 2022, U.S. patent application Ser. No. 18/510,234, “METHODS FOR 3D TENSOR BUILDER FOR INPUT TO MACHINE LEARNING,’ filed May 23, 2024, and U.S. patent application Ser. No. 18/665,258, “USER INTERFACE FOR A TENSOR BUILDER TO CONSTRUCT IMAGES FOR INPUT TO MACHINE LEARNING,” filed Nov. 28, 2024.

Some generative AI models providers provide large language models (LLMs) for users, and some have begun to offer AI assistant extensions. The AI assistant extensions include several application programming interfaces (APIs) allowing users to access further capabilities. The further capabilities include prompts and files to add to the knowledge of the AI assistant and functions to allow the AI assistant to interact with local or web resources. The ability to interact with resources forms a bidirectional connection and not only requests actions but expects responses, a relatively new feature. The user has the ability to add files that can extend the knowledge of the AI assistant. The APIs now allow the use of Retrieval Augmentation Generation (RAG) allowing for the augmentation of an AI model with domain-specific information.

Generative AI models undergo a form of training in which the models learn underlying patterns in the training data and use that training to produce new data based upon the input, which, in the embodiments here, come from the user from the AI Assistant. RAG differs from training in that RAG may result from the generative AI model itself seeking information. RAG provides generative AI models to employ domain-specific data and information, including updates. The generative AI model retrieves the information prior to providing responses. The system may include resources internal to a firewall or otherwise controlled to allow the generative AI model to access.

In addition, the system may employ vector databases for storing information using embeddings. While vector databases are a key component of RAG systems, they are distinct technologies. Vector databases enable semantic search by representing data, such as images, graphics, text, numeric values, etc., as vectors that can be compared for similarity. In RAG, the embeddings are retrieved from the vector database and used to augment a language model with domain-specific knowledge.

The API features are sufficient for a user to describe features of a large set of waveforms and then have the AI Assistant API and AI generative model fill in the parameters to a standard workflow that creates waveforms.

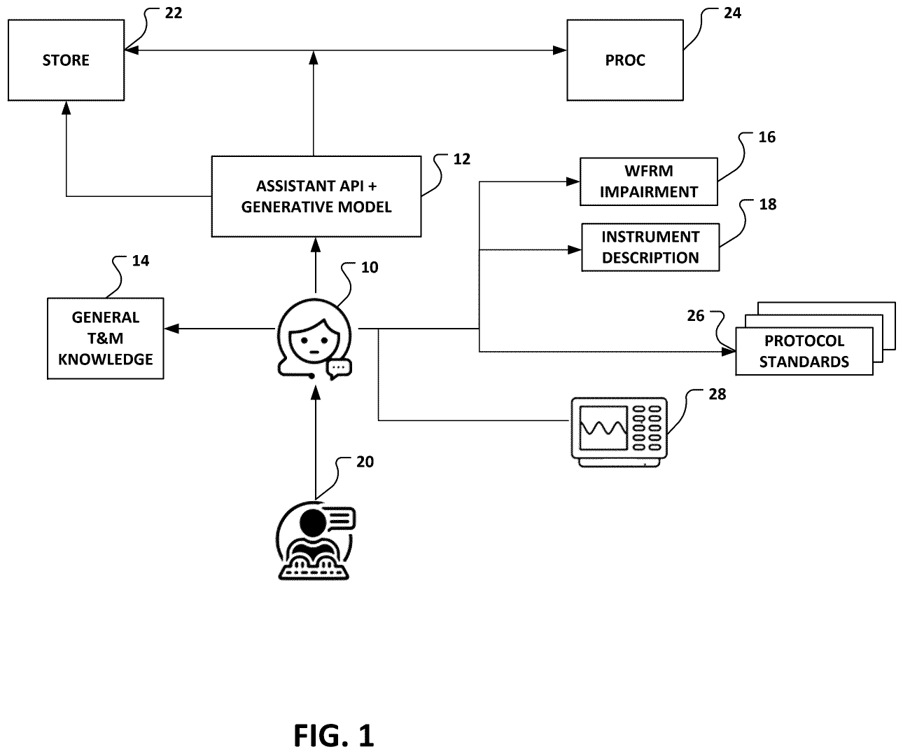

FIG. 1 shows an embodiment of a system configuration for an AI assistant for a testing system. The user 20 interacts with the generative model 12 through an AI assistant application programming interface (API) 10. The interaction with the API 10 may occur directly, such as by the user 20 providing a script that calls the API 10, or through a user interface such as a chat bot interface or other user input window that takes prompt inputs. The AI assistant 10 may access general test and measurement (T&M) knowledge 14. Based upon the user configuration, assistant 10 may also access information about waveform impairments 16, such as jitter, noise, etc., and instrument descriptions 18, discussed in more detail below. In addition, the assistant 10 may also access various protocol standards 26, such as PCI Gen X (Peripheral Component Interface), USB Gen X (Universal Serial Bus), and LAN (Local Area Network), where Gen X indicates any generation. Further, the system may include one or more test and measurement instruments such as test and measurement instrument 28. The test and measurement instrument may comprise an oscilloscope, including a mixed signal oscilloscope, a digital multimeter, spectrum analyzers, among many other examples. The test and measurement instrument may include a waveform generation capability such as an arbitrary waveform generator. The test and measurement instrument comprises any instrument that can receive signals from devices under test and produce waveforms.

The generative AI model, including any LLMs, may comprise computer code operating on one or more processors such as processor 24. The processors may reside on one or more computing devices, including test and measurement instruments 28, servers operating remotely from the user, a local computing device to the user 20, etc. The system may include any combination of the above devices and other computing devices. The resulting waveforms may be stored in store 22.

With embodiments of the system disclosed herein, the user 20 may request a set of waveforms in many different ways. An example may comprise, but is not limited to, “Create 10,000 PCIe Gen 7 waveforms using the SSPRQ (short stress pattern random quaternary) pattern for all legal symbol rates and amplitudes. Randomly vary the time interval error (TIE) for each waveform using a normal distribution with a standard deviation (stddev) of ¼ unit interval (UI). Randomly the noise varies between 1% to 10%. Add metadata to the waveform with the parameters used to define it.” Another example may be “Create 35000 Waveforms based on the derived symbols, data rate, and amplitude from the waveform file “pcie_gen7_03_30.wfm”. Randomly vary the TIE using a normal distribution where stddev=0.1UI. Vary the impairment by randomly choosing an s4p file from the directory ‘cable_models’ and using it as the model for the waveform. Add metadata to the waveform with the parameters used to define it.” Yet another example comprises “Create 60000 waveforms by randomly choosing from the directory ‘PCIe7_Examples’ and using the data rate, bit sequence, and amplitude. Then varying the TIE so that the patterns 001 and 110 have a transition time of [ . . . ], and the patterns 101 and 010 have the transition time of [ . . . ] . . . ”

The outputs of the examples from the present disclosure include but are not limited to an analog time domain waveform(s), fast-frame analog data where “fast frame” refers to a segmented memory acquisition mode designed to save memory when acquiring a large number of low duty cycle events, waveform database from folding created data sets, a digital time domain waveform(s), and an IQ (in-phase and quadrature waveform for radio frequency (RF).

The user 20 can use many different parameters to define a waveform. The discussion below provides examples without limitation. The user 20 may define test patterns, meaning sets of patterns or symbols repeated one or more times that represent the data in a pattern, such as pseudorandom binary sequences (PRBS7, 9, 15, 23 . . . ), SSPRQ, etc. The user 20 may also define modulation techniques such as pulse amplitude modulation 4 (PAM4), non-return-to-zero (NRZ), quadrature amplitude modulation (QAM4, QAM16). Some test patterns may imply a corresponding modulation, such as SSPRQ implies PAM4 modulation.

Some of the parameters may involve parameters like data rate of the bit or symbols in a pattern, frequency in cycles per second that may be the carrier frequency for RF signals, signal amplitude, signal offset, and whether the signal is differential or single ended. For differential signals, the user may also include the timing between the differential signals. The parameters may also involve signal impairments, such as inter-channel skew that shows timing errors in differential signals, noise, jitter, including random jitter and deterministic jitter, intersymbol interference (ISI), and bit and symbol error rates.

Other parameters may include whether spread spectrum clocking (SSC) is used, read files for s-parameters, waveforms, etc., write files that specify write waveform or other files. The parameters may include a count of how many waveforms to generate, statistical specifications for a rate of occurrence for randomly specified events. In addition, the user 20 may specify a target instrument, such as an oscilloscope, or arbitrary waveform generator (AWG). User 20 may also provide power of the signal, the slope of the power of the signal over the duration of a signal in RF, pulse repetition interval for RF. As shown in FIG. 1, the system may also take into account standards, such as PCI (peripheral component interface) or PCI-E (PCI-express), Universal Serial Bus (USB), including the packets and/or fields associated with a protocol.

The user 20 can provide any of the above inputs to AI assistant 10. In some embodiments, the user inputs may comprise: enumerations, such as PRBS7, PRBS10, and so on for pattern definitions; real values plus optional units, such as the data rate, which might be 2.7 GHz where the value passed would be 2.7e⁹ with the units Hertz; statistical descriptions, such as a value with a mean of 0.1UI and a standard deviation of 0.05UI; counts of the number of items requested, random selections, which may comprise randomly chose options from a set of options, such as files in a directory; and depending relationships, for example definitions of relationships between parameters. Statistical descriptions involve randomly picking a value based on the statistical specification. If a large enough population is measured from the definition, the assistant API 10 and AI model approximates the specified statistical definition. For example, a request for 100 waveforms with a data rate with a mean of 2.7 GHz and a standard deviation of 160 MHz may generate 100 waveforms, each having a different data rate, such that the data rates of the 100 waveforms have a normal distribution centered at 2.7 GHz.

In some embodiments, more complex behaviors can be defined using templates and creation rules. For example, the example prompt “100 I2C Packets for 3 10-bit devices where 1 device is not responding,” might use templates for 10-bit data packets, and creation rules that specify how the data packets are converted into “clk” and “data” analog signals. The templates and creation rules allow complex behavior to be added without needing a lot of code. A template definition in XML, JSON, YAML, or other description language allows data templates and creation rules to be defined in a generic way.

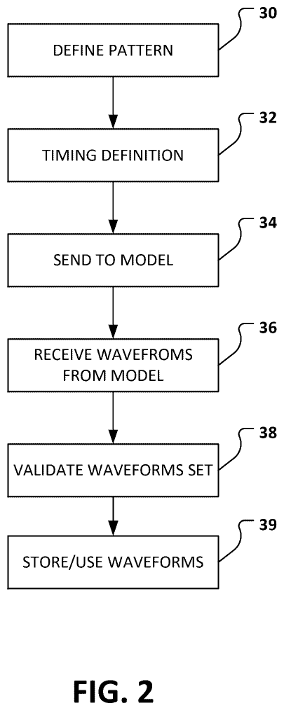

FIG. 2 shows a flowchart of an embodiment of a flowchart of a workflow for generating a waveform using a system such as that shown in FIG. 1. In the embodiment of FIG. 2, the method begins with defining the pattern at 30. The user may define the pattern according to any of the manners discussed above. The definition may include the data rate, and bit errors, and/or any other of the parameters discussed above, as examples. The generative AI model may call the functions provide parameters related to the output waveform. In cases where the user does not describe items, the system may provide reasonable defaults. The system provides a timing definition 32, the assistant then sends the patterns and definitions to the model at 34. The model returns the waveforms at 36.

At 38, the user may validate the set of waveforms to ensure the set meets the specification given at the input to the process. For example, if the input to the process set a TIE that has a specific standard deviation, the overall waveform set may be evaluated to determine that the waveforms complied with that specification. After validation, the system may then store the waveforms for later use or employ the waveforms in a test and measurement instrument at 39.

After the user requests a set of waveforms, the Assistant API and the AI model collect information from the user input and use the workflow in FIG. 2 to generate a waveform. In some examples, the Assistant API and generative AI model uses the workflow in FIG. 2 for each requested waveform. For example, if the user requests 100 waveforms, the Assistant API and AI model use the workflow in FIG. 2 100 times to generate 100 waveforms. In the exemplary workflow shown in FIG. 2, the functions called by the system provide parameters related to the output waveform. As mentioned above, when the user does not describe items, reasonable defaults are used. In addition, the generative AI model may also adjust the waveform to be generated to account for particular characteristics, capabilities, and limitations, such as the sample rate, memory depth, or cycle-related performance.

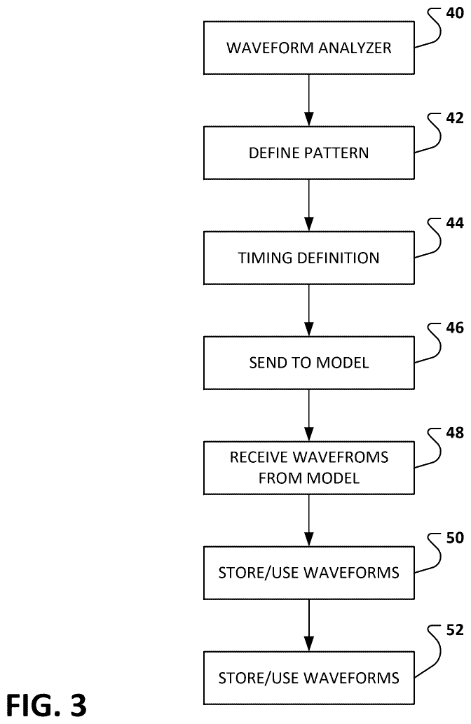

When the system uses a waveform as an input, the workflow is altered as follows in FIG. 3. In FIG. 3, the input waveform is put through a waveform analyzer at 40. The process then continues as discussed in FIG. 2, through defining the pattern at 42, determining the timing definitions at 44, sending the information to the model at 46, and receiving the waveforms through the assistant at 48. The waveforms are validated to ensure they meet the desired specifications at 50 and then used or stored at 52.

The waveform analyzer uses analysis functions to determine elements of the waveform, such as pattern, data rate, and amplitude. The elements are passed along if a connection is mentioned in the prompt to the AI Assistant. For example, a user may provide measured features of an existing waveform as a partial input and the AI model may provide a set of waveforms as outputs with those measured features with any missing parameters filled in by the Assistant.

In addition to creating new waveform sets, the waveforms generated by the AI model may also augment an existing waveform set. For example, assume a particular set or repository of waveforms has a current TIE with a peak-to-peak of 5 picoseconds (ps), but the user wants the overall set to have a peak-to-peak of 5.6 ps and a standard deviation of 3.2 ps. The AI model may take the current TIE measures of the set and a desired final TIE measures and generate additional waveforms that would shift the TIE measure of the set to meet the desired final TIE measures.

Though creating waveforms is a common task, using an AI model combined with domain-specific knowledge allows a large set of unique waveforms to be created with labels for machine learning. The waveforms can be indistinguishable from waveforms captured using an oscilloscope and a device under test (DUT). The waveforms can be useful in machine learning scenarios or other use cases where access to waveforms from DUTs is unavailable, such as early in the creation of a bus standard.

The present disclosure involves providing protocol standard knowledge and instrument knowledge to be loaded into the AI assistant so that the user can refer to standards and key aspects of a signal rather than having to program the knowledge as part of a waveform creation workflow specifically. Additionally, the present disclosure provides a standard workflow for the creation of the output data into which the AI model provides specific values to one or more of the parameters that the workflow can control. The present disclosure involves the workflow having a parameter definition as a statistical definition rather than a specific value, which means that each time the workflow is run, a new, unique waveform will be created each time the workflow is run based on the statistical definition provided. The present disclosure also involves many waveforms being created, named, and stored based on parameters defined in the prompt.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a computing device, comprising: one or more memories including test and measurement knowledge; a generative artificial intelligence (AI) model having access to the one or more memories; a display; user controls to allow the user to provide inputs; and one or more processors configured to execute that code that causes the one or more processors to: access an application programming interface (API) of an AI assistant for the generative AI model to allow the user to interact with the AI assistant; receive one or more user inputs through one or more of the API or a user interface, the user inputs providing a description of one or more waveforms to be generated; use the AI assistant to develop each waveform definition from the description and access the generative AI model; receive one or more waveforms from the AI assistant; and store the one or more waveforms.

Example 2 is the computing device of Example 1, wherein one or more processors are further configured to perform retrieval-augmented generation (RAG) to access information outside the memories.

Example 3 is the computing device of either of Examples 1 and 2, wherein the one or more memories store a corpus of test and measurement knowledge.

Example 4 the computing device of any of Examples 1 through 3, wherein the user inputs comprise one or more of enumerations, real values, statistical description, counts, and selections from a set of options.

Example 5 is the computing device of any of Examples 1 through 4, wherein the code that causes the one or more processors to receive the one or more user inputs comprises code that causes the one or more processors to present a user interface having templates with associated creation rules.

Example 6 is the computing device of any of Examples 1 through 5, wherein the code that causes the one or more processors to receive the one or more user inputs comprises code that causes the one or more processors to provide templates and definitions for inputs.

Example 7 is the computing device of any of Examples 1 through 6, wherein the code that causes the one or more processors to develop the waveform definitions comprises code that causes the one or more processors to use defaults when the user inputs are not received.

Example 8 is the computing device of any of Examples 1 through 7, wherein the code that causes the one or more processors to develop waveform definitions comprises taking measured features of an existing waveform as input to produce new waveforms with the specified features.

Example 9 is the computing device of Examples 1 through 8, wherein the one or more processors are further configured to validate the one or more waveforms received from the AI Assistant against the waveform definition.

Example 10 is a computer-implemented method to produce one or more waveforms, comprises: accessing an application programming interface (API) of an AI assistant for a generative artificial intelligence (AI) model to allow the user to interact with the AI assistant; receiving one or more user inputs through one or more of the API or a user interface, the user inputs providing a description of one or more waveforms to be generated; using the AI assistant to develop a waveform definition from the description and access the generative AI model receiving one or more waveforms generated by the generative AI model from the AI assistant; and storing or using the one or more waveforms.

Example 11 is the computer-implemented method of Example 10, further comprising using retrieval-augmented generation (RAG) to access information outside a system in which the generative AI model resides.

Example 12 is the computer-implemented method of either of Examples 10 or 11, wherein the one or more memories store a body of test and measurement knowledge accessible by the generative AI model.

Example 13 is the computer-implemented method of any of Examples 10 through 12, wherein the user inputs comprise one or more of enumerations, real values, statistical description, counts, and selections from a set of options.

Example 14 is the computer-implemented method of Examples 10 through 13, wherein presenting the user interface comprises presenting the user interface having templates with associated creation rules.

Example 15 is the computer-implemented method of Examples 10 through 14, wherein receiving user inputs through a user interface comprises providing templates and definitions for inputs.

Example 16 is the computer-implemented method of Examples 10 through 15, wherein developing the waveform definitions comprises using defaults when the user inputs are not received.

Example 17 is the computer-implemented method of Examples 10 through 16, wherein the code that causes the one or more processors to develop waveform definitions comprises taking measured features of an existing waveform as input to produce new waveforms with the measured features.

Example 18 is the computing device of Examples 10 through 17, further comprising validating the one or more waveforms received from the AI Assistant against the waveform definition.

The previously described versions of the disclosed subject matter have many advantages that were either described or would be apparent to a person of ordinary skill. Even so, these advantages or features are not required in all versions of the disclosed apparatus, systems, or methods.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of this disclosure have been illustrated and described for purposes of illustration, it will be understood that various modifications may be made without departing from the spirit and scope of the invention. Accordingly, the invention should not be limited except as by the appended claims.

1. A computing device, comprising:
one or more memories including test and measurement knowledge;
a generative artificial intelligence (AI) model having access to the one or more memories;
a display;
user controls to allow the user to provide inputs; and
one or more processors configured to execute that code that causes the one or more processors to:
access an application programming interface (API) of an AI assistant for the generative AI model to allow the user to interact with the AI assistant;
receive one or more user inputs through one or more of the API or a user interface, the user inputs providing a description of one or more waveforms to be generated;
use the AI assistant to develop each waveform definition from the description and access the generative AI model;
receive one or more waveforms from the AI assistant; and
store the one or more waveforms.

2. The computing device as claimed in claim 1, wherein one or more processors are further configured to perform retrieval-augmented generation (RAG) to access information outside the memories.

3. The computing device as claimed in claim 1, wherein the one or more memories store a corpus of test and measurement knowledge.

4. The computing device as claimed in claim 1, wherein the user inputs comprise one or more of enumerations, real values, statistical description, counts, and selections from a set of options.

5. The computing device as claimed in claim 1, wherein the code that causes the one or more processors to receive the one or more user inputs comprises code that causes the one or more processors to present a user interface having templates with associated creation rules.

6. The computing device as claimed in claim 1, wherein the code that causes the one or more processors to receive the one or more user inputs comprises code that causes the one or more processors to provide templates and definitions for inputs.

7. The computing device as claimed in claim 1, wherein the code that causes the one or more processors to develop the waveform definitions comprises code that causes the one or more processors to use defaults when the user inputs are not received.

8. The computing device as claimed in claim 1, wherein the code that causes the one or more processors to develop waveform definitions comprises taking measured features of an existing waveform as input to produce new waveforms with the specified features.

9. The computing device as claimed in claim 1, wherein the one or more processors are further configured to validate the one or more waveforms received from the AI Assistant against the waveform definition.

10. A computer-implemented method to produce one or more waveforms, comprises:
accessing an application programming interface (API) of an AI assistant for a generative artificial intelligence (AI) model to allow the user to interact with the AI assistant;
receiving one or more user inputs through one or more of the API or a user interface, the user inputs providing a description of one or more waveforms to be generated;
using the AI assistant to develop a waveform definition from the description and access the generative AI model
receiving one or more waveforms generated by the generative AI model from the AI assistant; and
storing or using the one or more waveforms.

11. The computer-implemented method as claimed in claim 10, further comprising using retrieval-augmented generation (RAG) to access information outside a system in which the generative AI model resides.

12. The computer-implemented method as claimed in claim 10, wherein the one or more memories store a body of test and measurement knowledge accessible by the generative AI model.

13. The computer-implemented method as claimed in claim 10, wherein the user inputs comprise one or more of enumerations, real values, statistical description, counts, and selections from a set of options.

14. The computer-implemented method as claimed in claim 10, wherein presenting the user interface comprises presenting the user interface having templates with associated creation rules.

15. The computer-implemented method as claimed in claim 10, wherein receiving user inputs through a user interface comprises providing templates and definitions for inputs.

16. The computer-implemented method as claimed in claim 10, wherein developing the waveform definitions comprises using defaults when the user inputs are not received.

17. The computer-implemented method as claimed in claim 10, wherein the code that causes the one or more processors to develop waveform definitions comprises taking measured features of an existing waveform as input to produce new waveforms with the measured features.

18. The computer-implemented method as claimed in claim 10, further comprising validating the one or more waveforms received from the AI Assistant against the waveform definition.
